(19) United States
(12) Patent Application Publication
(10) Pub. No.: US 2026/0068496 A1
(43) Pub. Date: Mar. 5, 2026

(54) DISPLAY DEVICE, DISPLAY PANEL, AND METHOD OF MANUFACTURING DISPLAY PANEL

(71) Applicant: HKC CORPORATION LIMITED, SHENZHEN (CN)

(72) Inventors: Yangling TANG, SHENZHEN (CN); Zhisheng XIE, SHENZHEN (CN); Qin LIANG, SHENZHEN (CN); Zhi YANG, SHENZHEN (CN); Lidan YE, SHENZHEN (CN)

(73) Assignee: HKC CORPORATION LIMITED, SHENZHEN (CN)

(21) Appl. No.: 19/302,003

(22) Filed: Aug. 17, 2025

(30) Foreign Application Priority Data
Aug. 30, 2024 (CN) 202411218233.9

(51) Int. Cl. H10K 59/80; H10K 59/12; H10K 59/122; H10K 102/00

(52) U.S. Cl. CPC H10K 59/873; H10K 59/1201; H10K 59/122; H10K 2102/351

(57) ABSTRACT

A display device, a display panel, and a method of manufacturing the display panel are provided. The display panel has a display region and a border region located around the display region. The display panel further includes a dam structure. The dam structure is arranged in the border region. The dam structure includes a thickened structure, a body structure, and an eave structure sequentially stacked in a direction from a driving structure layer to an encapsulation structure layer. At least a side end of the eave structure extends beyond a top surface of the body structure. An orthographic projection of a top surface of a part of the thickened structure in contact with the body structure onto a bottom surface of the eave structure is located within the bottom surface of the eave structure.

### CROSS-REFERENCE TO RELATED APPLICATIONS

This application claims priority to Chinese Patent Application No. 202411218233.9, filed on Aug. 30, 2024 in the National Intellectual Property Administration of China, the contents of which are herein incorporated by reference in their entireties.

### TECHNICAL FIELD

The present disclosure relates to the technical field of displays, in particular, to a display device, a display panel, and a method of manufacturing the display panel.

### BACKGROUND

A light-emitting device, such as organic light emitting diode (OLED), is being increasingly widely applied to products such as televisions and mobile phones due to its characteristics such as lightweight, energy-saving, wide color gamut, high contrast ratio, etc. In the process of manufacturing OLEDs, an isolation structure between pixels is manufactured using a process route involving a maskless overhang structure (i.e., without using masks), so as to improve the display effect of the pixels. When a thin-film encapsulation barrier structure is manufactured by the process route involving the maskless overhang structure, defects such as cracks and voids easily occur in a lower side region of an eave structure within the overhang structure, thereby affecting subsequent processes.

### SUMMARY

Some embodiments of the present disclosure may provide a display device, a display panel, and a method of manufacturing the display panel

A first technical solution adopted by the present disclosure is to provide a display panel. The display panel has a display region and a border region located around the display region, and the display panel includes: a driving structure layer; an encapsulation structure layer, where the driving structure layer and the encapsulation structure layer are sequentially stacked on one another; and one or more dam structures, arranged in the border region and arranged between the driving structure layer and the encapsulation structure layer, where each of the one or more dam structures includes: a thickened structure; a body structure; and an eave structure, where the thickened structure, the body structure, and the eave structure are sequentially stacked in a direction from the driving structure layer to the encapsulation structure layer, at least a side end of the eave structure extends beyond a top surface of the body structure, and an orthographic projection of a top surface of a part of the thickened structure in contact with the body structure onto a bottom surface of the eave structure is located within the bottom surface of the eave structure.

A second technical solution adopted by the present disclosure is to provide a method of manufacturing a display panel. The method includes: obtaining a pre-processed panel, the pre-processed panel having a display region and a border region located around the display region, the pre-processed panel comprising a driving structure layer and a thickened layer sequentially stacked on one another, a barrier structure being arranged on the thickened layer in the border region, the barrier structure comprising a body structure and an eave structure stacked in a direction away from the thickened layer, and at least one end of the eave structure extending beyond a top surface of the body structure; sequentially removing a part of the thickened layer on a side of the eave structure extending beyond the top surface of the body structure to form a thickened structure on a side of the body structure away from the eave structure, and the thickened structure and the barrier structure cooperatively constituting a dam structure; where an orthographic projection of a top surface of a part of the thickened structure in contact with the body structure onto a bottom surface of the eave structure does not exceed an edge of a side end of the bottom surface of the eave structure extending beyond the body structure; and forming an encapsulation structure layer on a side of the driving structure layer where the dam structure is arranged.

A third technical solution adopted by the present disclosure is to provide a display device. The display device includes the display panel provided in the first technical solution and a power supply connected to the display panel and configured to supply power to the display panel.

### BRIEF DESCRIPTION OF THE DRAWINGS

To more clearly illustrate the technical solutions in the embodiments of the present disclosure, a brief introduction to the drawings used in some embodiments of the present disclosure is provided below. It is evident that the drawings described below are only some of the embodiments of the present disclosure. For those skilled in the art, additional drawings may be derived from these drawings without creative work.

FIG. 1 is a schematic planar structural view of a display panel provided by a technical solution in the related art.

FIG. 2 is a schematic cross-sectional view of the display panel in an A-A orientation in the embodiment of FIG. 1.

FIG. 3(a) is a schematic cross-sectional view of a barrier structure in the related art after a first inorganic encapsulation layer covers thereon.

FIG. 3(b) is a schematic cross-sectional view of a barrier structure in the related art after a second inorganic encapsulation layer covers thereon.

FIG. 4 is a schematic cross-sectional view of a display panel according to a first embodiment of the present disclosure.

FIG. 5 is a schematic cross-sectional view of a dam structure according to a second embodiment of the present disclosure.

FIG. 6 is a schematic cross-sectional view of a dam structure according to a third embodiment of the present disclosure.

FIG. 7 is a schematic flowchart of a method of manufacturing a display panel according to some embodiments of the present disclosure.

FIG. 8(a) is a schematic cross-sectional view of the dam structure corresponding to an operation S1 in the method of manufacturing the display panel shown in FIG. 7.

FIG. 8(b) is a schematic cross-sectional view of the dam structure corresponding to an operation S1 in the method of manufacturing the display panel shown in FIG. 7.

FIG. 8(c) is a schematic cross-sectional view of the dam structure corresponding to an operation S1 in the method of manufacturing the display panel shown in FIG. 7.

FIG. 8(d) is a schematic cross-sectional view of the dam structure corresponding to an operation S1 in the method of manufacturing the display panel shown in FIG. 7.

FIG. 8(e) is a schematic cross-sectional view of the dam structure corresponding to an operation S1 in the method of manufacturing the display panel shown in FIG. 7.

FIG. 9 is a schematic flowchart of some embodiments of an operation S3 in the method of manufacturing the display panel shown in FIG. 7.

FIG. 10(a) is a schematic cross-sectional view of the dam structure corresponding to the operation S3 shown in FIG. 9.

FIG. 10(b) is a schematic cross-sectional view of the dam structure corresponding to the operation S3 shown in FIG. 9.

FIG. 10(c) is a schematic cross-sectional view of the dam structure corresponding to the operation S3 shown in FIG. 9.

FIG. 10(d) is a schematic cross-sectional view of the dam structure corresponding to the operation S3 shown in FIG. 9.

FIG. 10(e) is a schematic cross-sectional view of the dam structure corresponding to the operation S3 shown in FIG. 9.

FIG. 10(f) are schematic cross-sectional views of the dam structure corresponding to the operation S3 shown in FIG. 9.

FIG. 11 is a schematic structural view of a display device according to some embodiments of the present disclosure.

FIG. 12 is a schematic structural view of a display device according to some embodiments of the present disclosure.

### DETAILED DESCRIPTION

The following provides a detailed description of the technical solutions in some embodiments of the present disclosure with reference to the accompanying drawings.

In the following description, specific details such as particular system structures, interfaces, and technologies are presented for illustrative purposes and not for the purpose of limitation, to provide a thorough understanding of the present disclosure.

The technical solutions in some embodiments of the present disclosure will be clearly and completely described below with reference to the accompanying drawings. It is evident that the described embodiments are only part of the embodiments of the present disclosure and not all embodiments. Based on the embodiments of the present disclosure, all other embodiments obtained by those skills in the art without any creative work fall within the scope of the present disclosure.

The terms “first”, “second”, and “third” in some embodiments of the present disclosure are merely used for descriptive purposes and should not be construed as indicating or implying relative importance or implicitly indicating the quantity of the indicated technical features. Thus, the features limited by “first”, “second”, and “third” may explicitly or implicitly include at least one such feature. In the description of the present disclosure, “a plurality of” means at least two, for example, two, three, etc., unless specifically and explicitly limited otherwise. All directional indications (such as up, down, left, right, front, back, etc.) in the embodiments of the present disclosure are only used to explain the relative positional relationships, motion situations, etc., among the components under a specific posture (as shown in the figures). When the specific posture changes, the directional indications shall be changed accordingly. Furthermore, the terms “including” and “having” and any variations thereof are intended to cover non-exclusive inclusion. For example, a process, method, system, product, or device that includes a series of steps or units is not limited to those explicitly listed steps or units but may further optionally include other steps or units not listed, or may further optionally include other inherent steps or units of such process, method, product, or device.

As referred to herein, “embodiment” means that a specific feature, structure, or characteristic described in connection with the embodiment may be included in at least one embodiment of the present disclosure. The appearance of the phrase in various places in the specification are not necessarily all referring to the same embodiment, nor are they mutually exclusive alternative embodiments. It is explicitly and implicitly understood by those skills in the art that the embodiments described herein may be combined with other embodiments.

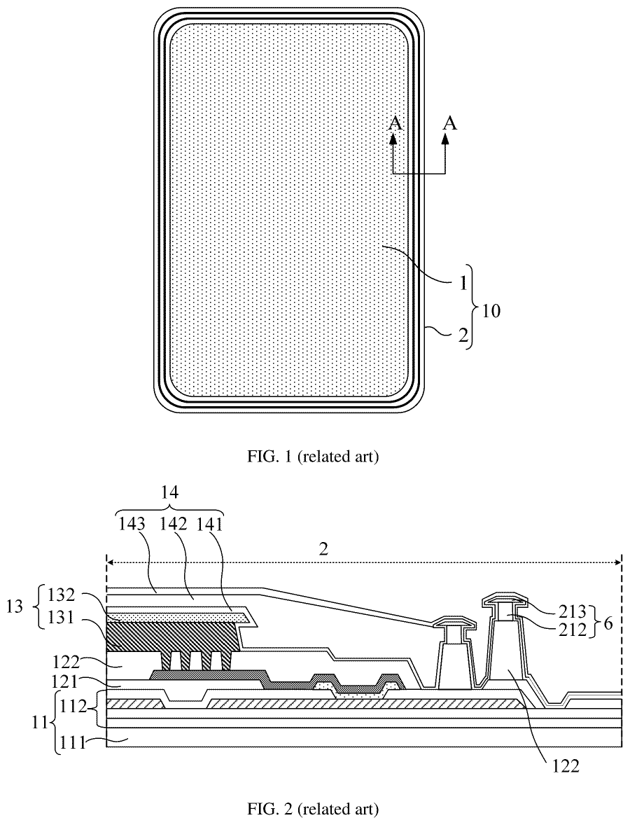

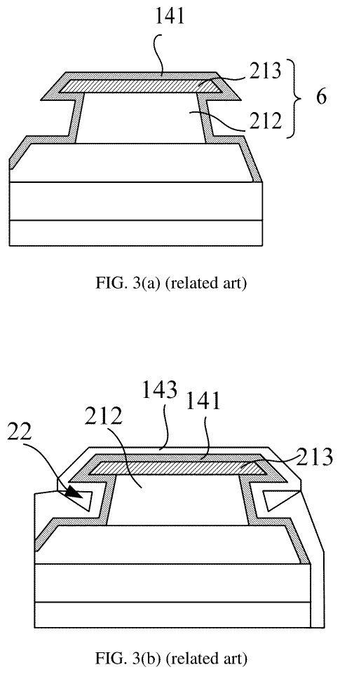

As shown in FIGS. 1 to 3(b), FIG. 1 is a schematic planar structural view of a display panel provided by a technical solution in the related art, FIG. 2 is a schematic cross-sectional view of the display panel in an A-A orientation in the embodiment of FIG. 1, FIG. 3(a) is a schematic cross-sectional view of a barrier structure in the related art after a first inorganic encapsulation layer covers thereon, and FIG. 3(b) is a schematic cross-sectional view of a barrier structure in the related art after a second inorganic encapsulation layer covers thereon.

At present, when manufacturing a thin-film encapsulation structure directly through a process route using a maskless overhang structure, defects such as cracks and voids 22 easily occur in a lower side region of an eave structure 213 of the overhang structure. In some embodiments, in a direction substantially perpendicular to the display panel 10, the display panel 10 includes a driving structure layer 11, a pixel defining layer 122, and an encapsulation structure layer 14 sequentially stacked on one another. The display panel 10 further includes a barrier structure 6. The barrier structure 6 is arranged in the border region 2 and is located between the driving structure layer 11 and the encapsulation structure layer 14. The barrier structure 6 includes a body structure 212 and an eave structure 213 that are sequentially stacked in a direction from the driving structure layer 11 to the encapsulation structure layer 14. An edge of the eave structure 213 extends beyond a top surface of the body structure 212. The encapsulation structure layer 14 includes a first inorganic encapsulation layer 141, an organic encapsulation layer 142, and a second inorganic encapsulation layer 143 sequentially stacked in a direction away from the driving structure layer 11. The organic encapsulation layer 142 is an ink jet print (IJP) layer. The barrier structure 6 is configured to block the flow leveling of the organic encapsulation layer 142. The first inorganic encapsulation layer 141 and the second inorganic encapsulation layer 143 are stacked on the driving structure layer 11 that is exposed and stacked on an outer wall surface of the barrier structure 6. Since the edge of the eave structure 213 of the barrier structure 6 extends beyond the top surface of the body structure 212, a part of the second inorganic encapsulation layer 143 on an end part of the eave structure 213 that extends beyond the top surface of the body structure 212 is easily connected with another part of the second inorganic encapsulation layer 143 located on the driving structure layer 11, thereby forming a void 22 among an outer side surface of the body structure 212, a bottom surface of the eave structure 213 extending beyond the top surface of the body structure 212, and a top surface of the driving structure layer 11. When the display panel 10 is heated, due to the thermal expansion and contraction of the air in the void 22, cracks may easily appear in the second inorganic encapsulation layer 143, thereby affecting the encapsulation performance of the encapsulation structure layer 14.

Furthermore, when another wiring layer is required to be arranged on the encapsulation structure layer 14 of the display panel 10, due to the instability of the structure of the encapsulation structure layer 14, there is a risk that the wiring layer laid on the encapsulation structure layer 14 may be prone to disconnecting.

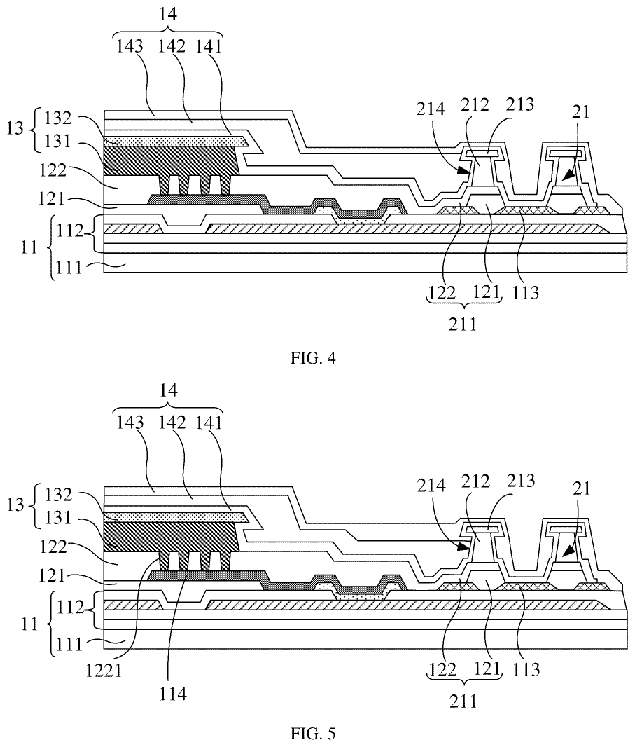

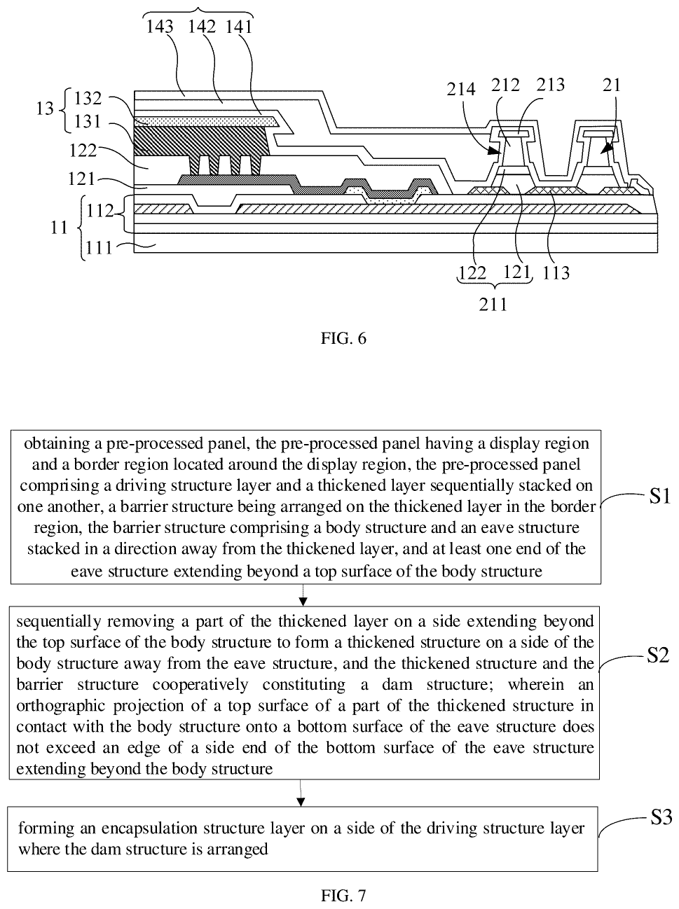

As shown in FIGS. 4 to 6, FIG. 4 is a schematic cross-sectional view of a display panel according to a first embodiment of the present disclosure, FIG. 5 is a schematic cross-sectional view of a dam structure according to a second embodiment of the present disclosure, and FIG. 6 is a schematic cross-sectional view of a dam structure according to a third embodiment of the present disclosure.

Based on the above problems, as shown in FIG. 4, some embodiments of the present disclosure provide a display panel 10. The display panel 10 may have a display region 1 and a border region 2 located around or surrounding the display region 1 (as shown in FIGS. 1-2). The display panel 10 may include a driving structure layer 11 and an encapsulation structure layer 14 sequentially stacked on one another. The display panel 10 may further include a dam structure 21. The dam structure 21 may be arranged in the border region 2 and may be arranged between the driving structure layer 11 and the encapsulation structure layer 14. The dam structure 21 may include a thickened structure 211, a body structure 212, and an eave structure 213 sequentially stacked in a direction from the driving structure layer 11 to the encapsulation structure layer 14. At least a side end of the eave structure 213 may extend beyond a top surface of the body structure 212. An orthographic projection of a top surface of a part of the thickened structure 211 in contact with the body structure 212 onto a bottom surface of the eave structure 213 may not exceed or extend beyond an edge of the side end of the bottom surface of the eave structure 213 that extends beyond the body structure 212.

The dam structure 21 provided in some embodiments of the present disclosure, by arranging in such a way that the orthographic projection of the top surface of the part of the thickened structure 211 in contact with the body structure 212 onto the bottom surface of the eave structure 213 may not extend beyond the edge of the side end of the bottom surface of the eave structure 213 that extends beyond the body structure 212, may reduce the probability of a void being formed between a part of the encapsulation structure layer 14 covering the side end of the bottom surface of the eave structure 213 extending beyond the body structure 212 and another part of the encapsulation structure layer 14 covering the top surface of the thickened structure 211, thereby improving the reliability of the display panel 10.

The driving structure layer 11 may include a substrate 111 and a driving substrate 112 sequentially stacked on one another.

In some embodiments, the display panel 10 may further include a metal layer 113, a planarization layer 121, and a pixel defining layer 122 sequentially stacked on one another. The metal layer 113 may be arranged on a surface of a side of the driving substrate 112 away from the substrate 111. In some embodiments, the metal layer 113 may also be a wiring layer in the driving substrate 112. The planarization layer 121 may be configured to fill a recessed region on the driving substrate 112 or the metal layer 113, and may form a smooth and flat surface on a side away from the driving structure layer 11. A material of the planarization layer 121 may be silicone resin, acrylic resin, polyimide, etc. The pixel defining layer 122 may be arranged on a surface of a side of the planarization layer 121 away from the driving substrate 112. A plurality of windows that are spaced apart from each other may be formed in the pixel defining layer 122. Each window serves as one sub-pixel region in which a corresponding one light-emitting device is arranged. The light-emitting device may include an anode electrode 114, a hole injection layer, a hole transport layer, a light-emitting layer, an electron transport layer, an electron injection layer, and a cathode electrode stacked sequentially in a direction away from the driving structure layer 11.

A conductive isolation structure 13 may be arranged on the pixel defining layer 122 in the display region 1. The conductive isolation structure 13 may be configured to reduce the optical crosstalk between light-emitting devices in adjacent sub-pixel regions. The conductive isolation structure 13 may include a conductive structure 131 arranged on the pixel defining layer 122 and a roof structure 132 arranged on the conductive structure 131. An orthographic projection of the conductive structure 131 onto the driving substrate 112 may be at least partially overlapped with an orthographic projection of the anode electrode 114 onto the driving substrate 112. A plurality of conductive vias 1221 may be defined in a part of the pixel defining layer 122 in the overlapping region. The conductive structure 131 may be connected to the anode electrode 114 through at least one of the plurality of the conductive vias 1221. The anode electrode 114 may be electrically connected to a power line on the driving substrate 112 through another via. The conductive structure 131 may be electrically coupled with the cathode electrode in the display region 1, thereby realizing a signal connection between the cathode electrode and signal wiring.

The border region 2 may include at least one thickened structure 211 that is independently arranged. The thickened structure 211 may include a part of the planarization layer 121 and a part of the pixel defining layer 122 stacked on one another. In some embodiments, a number of the thickened structures 211 may be one or more. A part of the metal layer 113 is exposed through a gap between adjacent thickened structures 211. The cross-sectional shape of the thickened structure 211 in a first direction may be a regular trapezoid shape, an inverted trapezoid shape, a rectangle shape, etc. The first direction may refer to a direction substantially perpendicular to the display panel 10.

A body structure 212 and an eave structure 213 may be sequentially arranged on a surface of the thickened structure 211 on the side away from the driving structure. The body structure 212 and the conductive structure 131 may be arranged spaced apart from each other in the same layer. The eave structure 213 and the roof structure 132 may be arranged spaced apart from each other in the same layer. In some embodiments, a width of an orthographic projection of a bottom surface of the body structure 212 onto a top surface of the thickened structure 211 may be smaller than a width of the top surface of the thickened structure 211.

At least one side end of the eave structure 213 may extend beyond a top surface of the body structure 212. In some embodiments, a side end of the eave structure 213 close to or a side end of the eave structure 213 away from the display region 1 may extend beyond the top surface of the body structure 212. In some embodiments, both the side end of the eave structure 213 close to the display region 1 and the side end of the eave structure 213 away from the display region 1 may extend beyond the top surface of the body structure 212 in a direction away from a central axis of the eave structure 213 in the first direction.

An orthographic projection of the top surface of the part of the thickened structure 211 in contact with the body structure 212 onto the bottom surface of the eave structure 213 may not extend the edge of the side end of the bottom surface of the eave structure 213 that extends beyond the body structure 212.

In some embodiments, when the side end of the eave structure 213 close to the display region 1 extends beyond the top surface of the body structure 212, the orthographic projection of the top surface of the part of the thickened structure 211 in contact with the body structure 212 onto the bottom surface of the eave structure 213 may not exceed an edge of a side end of the eave structure 213 close to the display region 1. Furthermore, in order to reduce the probability of a void being formed between the part of the encapsulation structure layer 14 covering the side end of the bottom surface of the eave structure 213 extending beyond the body structure 212 and the another part of the encapsulation structure layer 14 covering the top surface of the thickened structure 211, the orthographic projection of the top surface of the part of the thickened structure 211 in contact with the body structure 212 onto the bottom surface of the eave structure 213 may be located on a side, which is away from the display region 1, of the edge of the side end of the eave structure 213 close to the display region 1. A part of the side end of the eave structure 213 close to the display region 1 may extend beyond the top surface of the body structure 212. The part of the side end of the eave structure 213 close to the display region 1, a sidewall surface of the body structure 212 close to the display region 1, and the top surface of a part of the thickened structure 211 close to the display region 1 may cooperatively define a recess 214 on a sidewall surface of the dam structure 21 close to the display region 1.

In some embodiments, the side end of the eave structure 213 away from the display region 1 may not extend beyond the top surface of the body structure 212. In some embodiments, an end surface of a side of the eave structure 213 away from the display region 1 and a sidewall surface of the body structure 212 away from the display region 1 may be located on the same plane. In some embodiments, an orthographic projection of the end surface of the side of the eave structure 213 away from the display region 1 onto the top surface of the body structure 212 may be located on a side of a side edge of the top surface of the body structure 212 that is close to the display region 1. The end surface of the side of the eave structure 213 away from the display region 1, the top surface of the part of the body structure 212 away from the display region 1, and a sidewall surface of the body structure 212 away from the display region 1 may cooperatively form a stepped structure.

In some embodiments, when the side end of the eave structure 213 away from the display region 1 extends beyond the top surface of the body structure 212, the orthographic projection of the top surface of the part of the thickened structure 211 in contact with the body structure 212 onto the bottom surface of the eave structure 213 may not exceed or extend beyond an edge of the side end of the eave structure 213 away from the display region 1. Furthermore, in order to reduce the probability of a void being formed between the part of the encapsulation structure layer 14 covering the side end of the bottom surface of the eave structure 213 that extends beyond the body structure 212 and the another part of the encapsulation structure layer 14 covering the top surface of the thickened structure 211, the orthographic projection of the top surface of the part of the thickened structure 211 in contact with the body structure 212 onto the bottom surface of the eave structure 213 may be located on the side of the edge of the side end of the eave structure 213 away from the display region 1. The side end of the eave structure 213 away from the display region 1 may extend beyond the top surface of another part of the body structure 212. The part of the side end of the eave structure 213 away from the display region 1, the sidewall surface of the body structure 212 away from the display region 1, and the top surface of another part of the thickened structure 211 away from the display region 1 may cooperatively define another recess 214 on a sidewall surface of the dam structure 21 away from the display region 1.

In some embodiments, the side end of the eave structure 213 close to the display region 1 may not extend beyond the top surface of the body structure 212. In some embodiments, an end surface of the side of the eave structure 213 close to the display region 1 and the sidewall surface of the body structure 212 close to the display region 1 may be located on the same plane. In some embodiments, an orthographic projection of the end surface of the side of the eave structure 213 close to the display region 1 onto the top surface of the body structure 212 may be located on a side, which is away from the display region 1, of a side edge of the top surface of the body structure 212 that is close to the display region 1. The end surface of the side of the eave structure 213 close to the display region 1, the top surface of the part of the body structure 212 close to the display region 1, and the sidewall surface of the body structure 212 close to the display region 1 may cooperatively form a stepped structure.

In some embodiments, when both the side end of the eave structure 213 close to the display region 1 and the side end of the eave structure 213 away from the display region 1 extend beyond the top surface of the body structure 212 in the direction away from the central axis of the eave structure 213 in the first direction, the orthographic projection of the top surface of the part of the thickened structure 211 in contact with the body structure 212onto the bottom surface of the eave structure 213 may not exceed or extend beyond the bottom surface of the eave structure 213. Furthermore, in order to reduce the probability of a void being formed between the part of the encapsulation structure layer 14 covering the side end of the bottom surface of the eave structure 213 that extends beyond the body structure 212 and the another part of the encapsulation structure layer 14 covering the top surface of the thickened structure 211, at least an end portion of the bottom surface of the eave structure 213 away from the display region 1 may extend beyond an end portion of the top surface of a part of the pixel defining layer 122 in contact with the dam structure 21 corresponding to the eave structure 213. In some embodiments, only the end portion of the bottom surface of the eave structure 213 away from the display region 1 may extend beyond the end portion of the top surface of the pixel defining layer 122. In some embodiments, both opposite ends of the bottom surface of the eave structure 213 may extend beyond the end portions of the top surface of the part of the pixel defining layer 122 in contact with the dam structure 21 corresponding to the eave structure 213.

One side end of the eave structure 213 may extend beyond the top surface of the body structure 212 close to the display region 1, and another side end of the eave structure 213 may extend beyond the top surface of the body structure 212 away from the display region 1. Each of the one side end and the another side end of the eave structure 213 may cooperate with a corresponding sidewall surface of the body structure 212 and the top surface of a corresponding region of a part of the pixel defining layer 122, such that the recesses 214 may be defined on both the sidewall surface of the dam structure 21 close to the display region 1 and the sidewall surface of the dam structure 21 away from the display region 1.

In some embodiments, a cross-sectional shape of each of the eave structure 213, the body structure 212, and the thickened structure 211 in the first direction may be a regular trapezoidal shape or rectangular shape.

In some embodiments, the encapsulation structure layer 14 may be arranged on a side of the driving structure layer 11 where the dam structure 21 is arranged. The encapsulation structure layer 14 may include a first inorganic encapsulation layer 141, an organic encapsulation layer 142, and a second inorganic encapsulation layer 143 sequentially stacked in a direction away from the driving structure layer 11.

The first inorganic encapsulation layer 141 may extend in the direction away from the display region 1 to the border region 2 and may cover an exposed surface of the dam structure 21. The first inorganic encapsulation layer 141 may cover an exposed part of the metal layer 113, the sidewall surfaces of the dam structure 21, an inner wall surface of the recess 214, and the top surface of the dam structure 21. In order to reduce the probability of a void 22 being formed in the first inorganic encapsulation layer 141, a total thickness of the thickened structure 211 and the body structure 212 may be at least greater than twice a thickness of the first inorganic encapsulation layer 141. To facilitate post-processing of the first inorganic encapsulation layer 141, a minimum distance between an end surface of the first inorganic encapsulation layer 141 on the side away from the display region 1 and an edge of a bottom surface of the planarization layer 121 in an outermost dam structure 21 of the one or more dam structures 21 on a side close to the end surface of the first inorganic encapsulation layer 141 may be not less than 2 micrometers.

The organic encapsulation layer 142 may extend in the direction away from the display region 1 to the border region 2. The dam structure 21 may block the leveling of the organic encapsulation layer 142, thereby reducing the risk that the organic encapsulation layer 142 flows to an outer side of the border region 2. A surface of the organic encapsulation layer 142 on a side away from the driving structure layer 11 may be not lower than (i.e., at a higher level than or at the same level as) the bottom surface of the eave structure 213 and not higher than (i.e., at a lower level than or at the same level as) the top surface of the eave structure 213.

The second inorganic encapsulation layer 143 may extend in the direction away from the display region 1 to the border region 2, and may cover an exposed part of the organic encapsulation layer 142 and an exposed part of the first inorganic encapsulation layer 141. The second inorganic encapsulation layer 143 may cover the organic encapsulation layer 142. The second inorganic encapsulation layer 143 may further include the metal layer 113, the sidewall surfaces of the dam structure 21, the inner wall surface of the recess 214, and the part of the first inorganic encapsulation layer 141 covering the top surface of the dam structure 21. The second inorganic encapsulation layer 143 may fill the recess 214 and covers an opening of the recess 214. A sidewall surface of the second inorganic encapsulation layer 143 away from the dam structure 21 may be flat, so that a void may not occur in the second inorganic encapsulation layer 143 filled in the recess 214, and the occurrence of cracking in subsequent wiring on the second inorganic encapsulation layer 143 may be mitigated.

In some embodiments, at least one of the body structure 212 and the eave structure 213 may be made of a metal material. A material of the body structure 212 and a material of the eave structure 213 may be different from each other. For example, the materials of the body structure 212 and the eave structure 213 may be different metals. In some embodiments, the material of the body structure 212 may be copper, etc. The material of the eave structure 213 may be aluminum, etc. In some embodiments, one of the body structure 212 and the eave structure 213 may be made of metal, and the other of the body structure 212 and the eave structure 213 may be made of an insulating material. The metal may include but may not be limited to copper, aluminum, etc. The insulating material may include but may not be limited to polyimide, etc.

In some embodiments, the number of the dam structures 21 may be one or more than one. When the number of the dam structures 21 is more than one, the more than one dam structures 21 may be spaced apart from each other, and the metal layer 113 may be exposed through a gap between adjacent dam structures 21.

In some embodiments, when the number of the dam structures 21 is two, the thickened structure 211 in the dam structure 21 close to the display region 1 may be independently arranged, that is, the thickened structure 211 in the dam structure 21 may be spaced apart from the pixel defining layer 122 and the planarization layer 121 stacked in the display region 1, as shown in FIG. 6, so as to reduce probability of the formation of the void in the recess 214 in a case where a surface of the organic encapsulation layer 142 on a side away from the driving structure layer 11 does not reach the bottom surface of the eave structure 213.

In some embodiments, the present disclosure may provide a method of manufacturing a display panel 10. The display panel 10 may include the following implementation operations. The display panel 10 manufactured by the method may correspond to the display panel 10 described in the above embodiments. In the following embodiments, in order to reduce the manufacturing processes, the body structure 212 and the conductive structure 131 may be arranged in the same layer and made of the same material. The eave structure 213 and the roof structure 132 may be arranged in the same layer and made of the same material.

As shown in FIG. 7, FIG. 7 is a schematic flowchart of a method of manufacturing a display panel according to some embodiments of the present disclosure.

At operation S1, a pre-processed panel may be obtained. The pre-processed panel may have a display region and a border region located around or surrounding the display region. The pre-processed panel may include a driving structure layer and a thickened layer sequentially stacked on one another. A barrier structure may be arranged on the thickened layer in the border region. The barrier structure may include a body structure and an eave structure stacked in a direction away from the thickened layer. At least one end of the eave structure may extend beyond a top surface of the body structure.

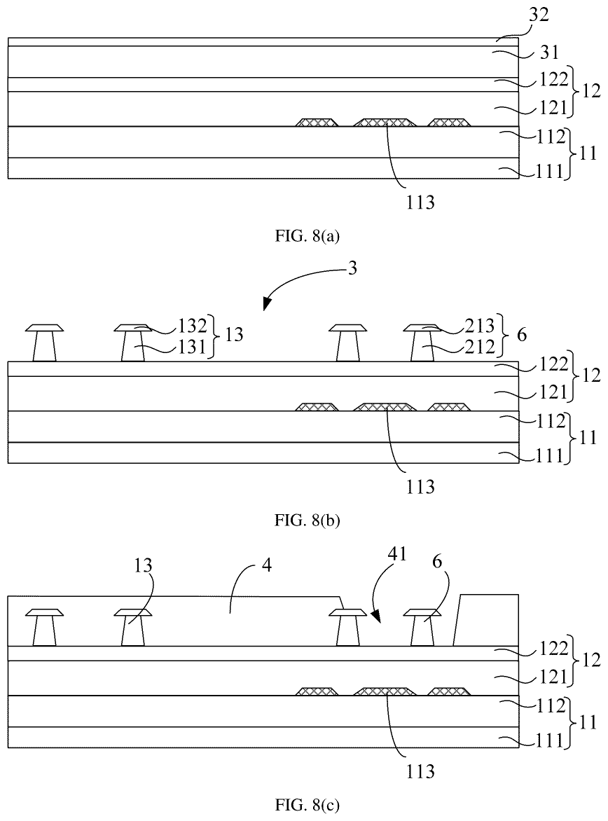

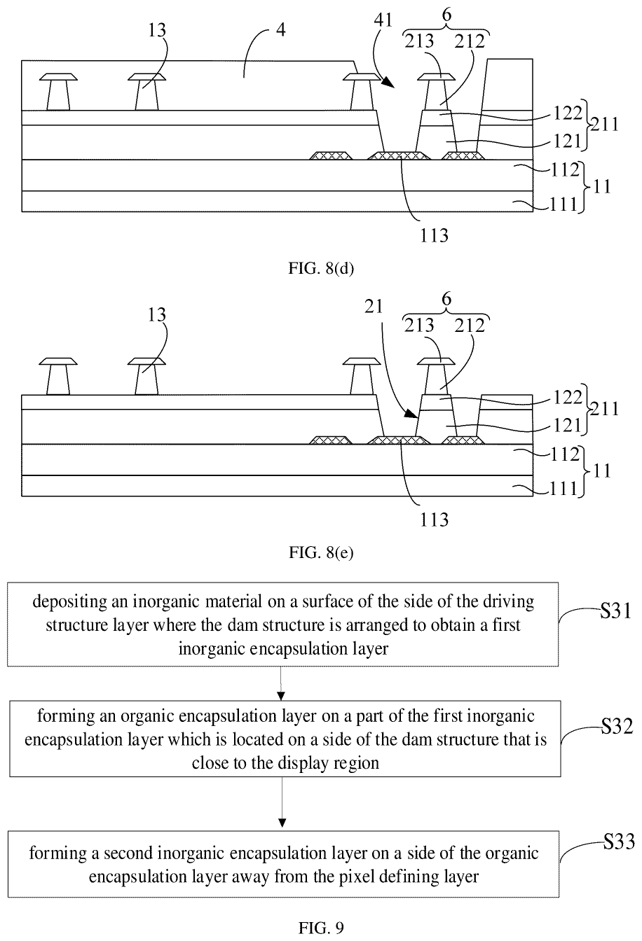

As shown in FIGS. 8(a) to 8(e), FIGS. 8(a) to 8(e) are schematic cross-sectional views of the dam structure corresponding to operation S1 in the method of manufacturing the display panel shown in FIG. 7.

In some embodiments, a driving substrate 112 may cover a surface of a side of the substrate 111 to form the driving structure layer 11. A metal layer 113 may cover a side of the driving substrate 112 away from the substrate 111. The metal layer 113 may be etched. A planarization layer 121 and a pixel defining layer 122 may be sequentially stacked on a surface of the metal layer 113 on a side away from the driving structure layer 11. The planarization layer 121 and the pixel defining layer 122 stacked in the direction away from the driving structure layer 11 may constitute a thickened layer 12.

A plurality of windows may be defined in a part of the pixel defining layer 122 in the display region 1. Each window may serve as one sub-pixel region, and each sub-pixel region may be configured for subsequent formation of a light-emitting device. In some embodiments, the pixel defining layer 122 and the planarization layer 121 in the border region 2 are structures extending along the entire layer without windows.

A first functional layer 31 and a second functional layer 32 sequentially covers a surface of a side of the pixel defining layer 122 away from the driving structure layer 11. Materials of the first functional layer 31 and the second functional layer 32 may be the same or different. The materials of the first functional layer 31 and the second functional layer 32 may be metals or insulating layers, and may be determined according to actual requirements, as shown in FIG. 8(a).

In the following embodiments, an example in which both the first functional layer 31 and the second functional layer 32 are metals is described in detail. The materials of the first functional layer 31 and the second functional layer 32 are different from each other. For example, the first functional layer 31 may be copper and the second functional layer 32 may be aluminum.

A photoresist layer may cover the second functional layer 32. The photoresist layer may completely cover the second functional layer 32. A plurality of first openings that are spaced apart from each other may be defined in the photoresist layer. The plurality of first openings may be defined by exposure and development. A part of the second functional layer 32 may be exposed via the plurality of first openings. The exposed part of the second functional layer 32 may be removed, so that the first functional layer 31 may be exposed through the openings. In some embodiments, the exposed part of the second functional layer 32 may be removed by wet etching. Thus, the second functional layer 32 may be formed into a plurality of second precursors.

The part of the first functional layer 31 exposed via the openings may be removed by means of, e.g., wet etching. Edges of the first functional layer 31 exposed via the openings, i.e., another part of the first function layer 31 covered by the edges of the second precursors, may also be removed by etching. As a result, the first functional layer 31 may be formed into a plurality of first precursors. A central axis of each second precursor in a direction substantially perpendicular to a surface of the driving structure layer 11 may coincide with a central axis of the corresponding first precursor in the direction substantially perpendicular to the surface of the driving structure layer 11. A width of each first precursor is smaller than that of the corresponding second precursor. The photoresist layer may be removed.

Each first precursor located in the display region 1 may serve as the conductive structure 131. Each second precursor may serve as the roof structure 132. The conductive isolation structure 13 described the above embodiments may include the conductive structure 131 and the roof structure 132 sequentially stacked on the pixel defining layer 122 in the display region 1. Each first precursor located in the border region 2 may serve as the body structure 212, and each second precursor may serve as the eave structure 213. The barrier structure 6 may include the body structure 212 and the eave structure 213 sequentially stacked on the pixel defining layer 122 in the border region 2. Through the above operations, a to-be-processed panel 3 may be obtained, as shown in FIG. 8(b).

At operation S2, a part of the thickened layer on a side of the eave structure extending beyond the top surface of the body structure may be sequentially removed, so as to form a thickened structure on a side of the body structure away from the eave structure. A dam structure may include the thickened structure and the barrier structure. An orthographic projection of a top surface of a part of the thickened structure in contact with the body structure onto a bottom surface of the eave structure may not exceed or extend beyond an edge of a side end of the bottom surface of the eave structure extending beyond the body structure.

In some embodiments, a first photoresist layer 4 may be formed on a side of the driving structure layer 11 where the barrier structure 6 is arranged. A first window 41 may be formed in the first photoresist layer 4. A surface of the barrier structure 6 and a surface of the thickened layer 12 surrounding the barrier structure 6 may be exposed through the first window 41. In some embodiments, the number of the barrier structure 6 may be two or more. A width of the first window 41 may be greater than a width of a gap between adjacent two barrier structures 6, as shown in FIG. 8(c).

At least the thickened layer 12 within the first window 41 that is not covered by the orthographic projection of the eave structure 213 onto the thickened layer 12 may be removed by means of, e.g., dry etching, so as to form the thickened structure 211 on a side of the body structure 212 away from the eave structure 213.

In some embodiments, only a part of the thickened layer 12 within the first window 41 that is not covered by the orthographic projection of the eave structure 213 onto the thickened layer 12 may be removed by dry etching. For example, only the pixel defining layer 122 may be removed, thereby exposing the planarization layer 121. In some embodiments, the pixel defining layer 122 and a part of the planarization layer 121 may be removed. A thickness of the removed planarization layer 121 may be less than a total thickness of the planarization layer 121.

In some embodiments, the pre-processed panel may further include a plurality of metal layers 113 that are spaced apart from each other, each of the plurality of metal layers 113 may be arranged between the thickened layer 12 and a driving electrode, and a material of the thickened layer 12 may be different from a material of each of the plurality of metal layers 113. In some embodiments, in order to reduce the risk of over-etching, the part of the thickened layer 12 within the first window 41 that is not covered by the orthographic projection of the eave structure 213 onto the thickened layer 12 may be removed by dry etching until the metal layer 113 is exposed, as shown in FIG. 8(d).

The first photoresist layer 4 may be removed.

In some embodiments, the dam structure 21 may include the formed thickened structure 211 and the body structure 212 and the eave structure 213 that are stacked on the top surface of the thickened structure 211. At least a side end of the eave structure 213 may extend beyond the top surface of the body structure 212. The orthographic projection of the top surface of the part of the thickened structure 211 in contact with the body structure 212 onto the bottom surface of the eave structure 213 may not exceed or extend beyond the edge of the side end of the bottom surface of the eave structure 213 extending beyond the body structure 212. In some embodiments, a central axis of the pixel defining layer 122 may coincide with the central axis of the eave structure 213. A width of the top surface of the part of the pixel defining layer 122 in contact with the dam structure 21 that belongs to the eave structure 213 may be smaller than a width of the bottom surface of the eave structure 213, as shown in FIG. 8(e).

At operation S3, an encapsulation structure layer may be formed on a side of the driving structure layer where the dam structure is arranged.

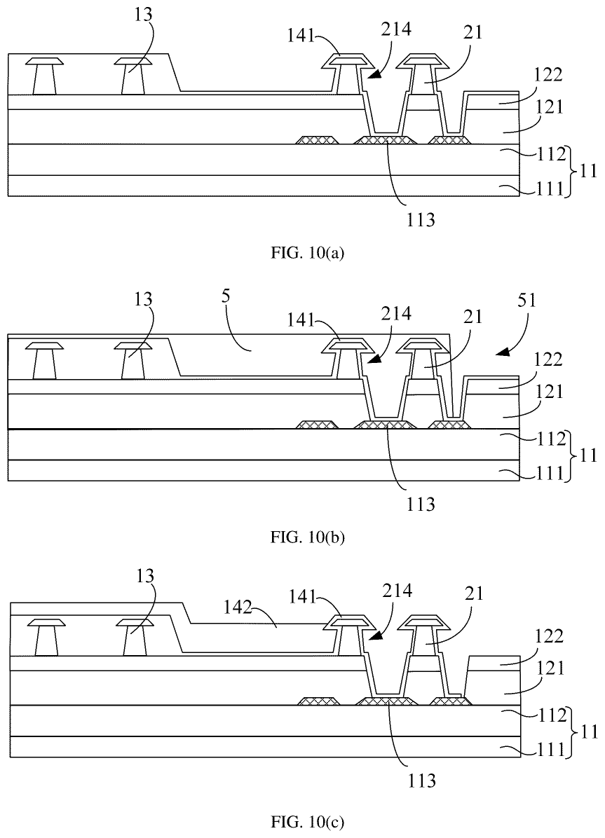

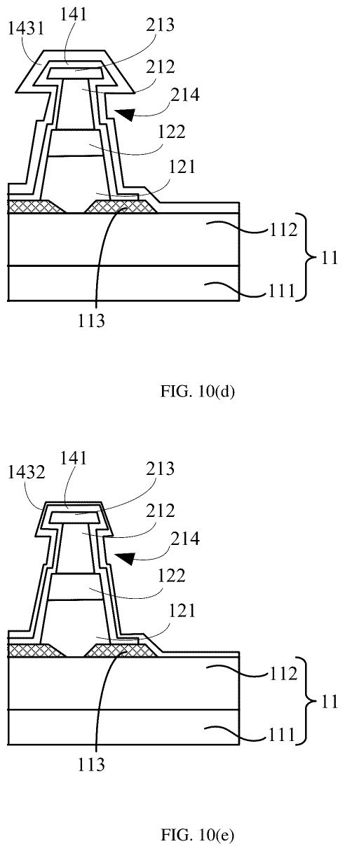

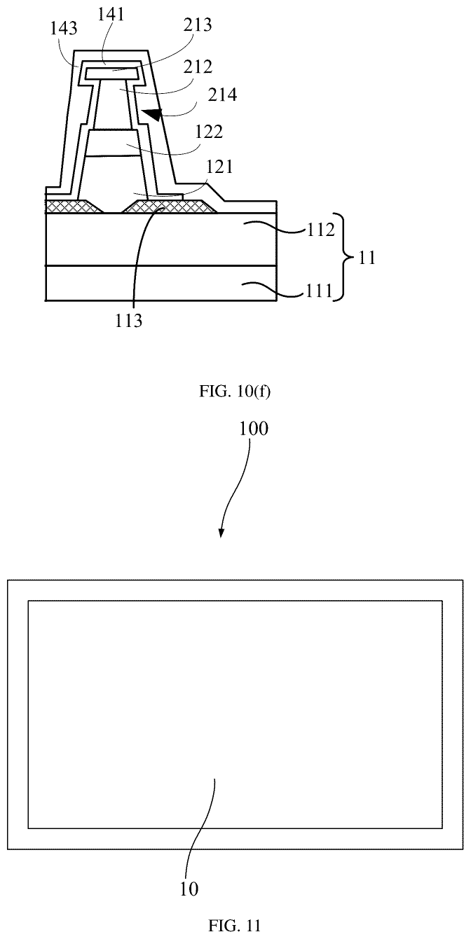

As shown in FIG. 9 and FIGS. 10(a) to 10(f), FIG. 9 is a schematic flowchart of some embodiments of an operation S3 in the method of manufacturing the display panel shown in FIG. 7, and FIGS. 10(a) to 10(f) are schematic cross-sectional views of the dam structure corresponding to the operation S3 shown in FIG. 9.

At operation S31, an inorganic material may be deposited on a surface of a side of the driving structure layer where the dam structure is arranged to form a first inorganic encapsulation layer.

In some embodiments, an inorganic material may be deposited on the surface of the side of the driving structure layer 11 where the dam structure 21 is arranged, to obtain the first inorganic encapsulation layer 141. In some embodiments, the deposition of the inorganic material may be achieved by chemical vapor deposition. The first inorganic encapsulation layer 141 may cover all exposed surfaces of the driving structure layer 11 on the side of the driving structure layer 11 where the dam structure 21 is arranged and an inner wall surface of the recess 214 located on a sidewall surface of the dam structure 21. The recess 214 on the sidewall surface of the dam structure 21 may be defined cooperatively by a part of the eave structure 213 extending beyond the top surface of the body structure 212, the sidewall surface of the body structure 212, and the top surface of a part of the thickened structure 211. In order to reduce the formation of a void in the first inorganic encapsulation layer 141, a total thickness of the thickened structure 211 and the body structure 212 may be at least greater than twice a thickness of the first inorganic encapsulation layer 141, as shown in FIG. 10(a).

In some embodiments, a second photoresist layer 5 may cover the first inorganic encapsulation layer 141. The second photoresist layer 5 may cover the first inorganic encapsulation layer 141. A second window 51 may be defined in a part of the first inorganic encapsulation layer 141 away from the display region 1. The second window 51 may be defined on a side of the outermost dam structure 21 away from the display region 1. A part of the first inorganic encapsulation layer 141 away from the display region 1 may be exposed through the second window 51. The exposed part of the first inorganic encapsulation layer 141 may be removed by means of, e.g., dry etching, to perform edge trimming of the first inorganic encapsulation layer 141. A minimum distance between an end surface of the first inorganic encapsulation layer 141 away from the display region 1 and an edge of a bottom surface of the planarization layer 121 in the outermost dam structure 21 on a side close to the end surface of first inorganic encapsulation layer 141 may be not less than (i.e., equal to or greater than) 2 micrometers, as shown in FIG. 10(b).

At operation S32, an organic encapsulation layer may be formed on a part of the first inorganic encapsulation layer which is located on a side of the dam structure that is close to the display region.

In some embodiments, an organic encapsulation material may be arranged on a surface of the first inorganic encapsulation layer 141 within the display region 1. The organic encapsulation material may be arranged by means of, e.g., inkjet printing. The organic encapsulation material may be flowable and flow from the display region 1 to the border region 2. The organic encapsulation material may be blocked by the dam structure 21, so that an organic encapsulation layer 142 may be formed by the organic encapsulation material on a surface of the first inorganic encapsulation layer 141 on a side away from the pixel defining layer 122, as shown in FIG. 10(c).

At operation S33, a second inorganic encapsulation layer may be formed on a side of the organic encapsulation layer away from the pixel defining layer.

In some embodiments, an inorganic material may be deposited on the organic encapsulation layer 142 and the dam structure 21 by means of, e.g., vapor deposition, to form a first sub-inorganic encapsulation layer 1431, as shown in FIG. 10(d).

Since the orthographic projection of the top surface of the part of the thickened structure 211 in contact with the body structure 212 onto the bottom surface of the eave structure 213 does not exceed or extend beyond the edge of the side end of the bottom surface of the eave structure 213 that extends beyond the body structure 212, the probability of a void 22 being formed in the recess 214 by the first sub-inorganic encapsulation layer 1431 may be reduced.

A surface of the first sub-inorganic encapsulation layer 1431 away from the driving structure layer 11 may be thinned to obtain a second sub-inorganic encapsulation layer 1432. In some embodiments, the thinning may be achieved by anisotropic dry etching. In the method of anisotropic dry etching, side etching or lateral etching is hard to achieve compared with isotropic dry etching. Therefore, a film thickness of a first part of the first sub-inorganic encapsulation layer 1431 on the driving structure layer 11, a film thickness of a second part of the first sub-inorganic encapsulation layer 1431 on the sidewall surface of the dam structure 21, and a film thickness of a third part of the first sub-inorganic encapsulation layer 1431 on the top surface of the dam structure 21 may be reduced, while a film thickness of a fourth part of the first sub-inorganic encapsulation layer 1431 covering the inner wall surface of the recess 214 formed on the sidewall surface of the dam structure 21 may not be reduced. That is, the thickness of a part of the second sub-inorganic encapsulation layer 1432 covering the inner wall surface of the recess 214 may be greater than the thickness of another part of the second sub-inorganic encapsulation layer 1432 covering the top surface of the dam structure 21, as shown in FIG. 10(e).

An inorganic material may further be deposited on the exposed surface of the second sub-inorganic encapsulation layer 1432 and then may be thinned until the inorganic material fills the recess 214. At least the first sub-inorganic encapsulation layer 1431 and the second sub-inorganic encapsulation layer 1432 may cooperatively serve as the second inorganic encapsulation layer 143. In some embodiments, multiple layers of sub-inorganic encapsulation layers formed on a side, which is away from the dam structure 21, of the first inorganic encapsulation layer 141 covering the dam structure 21 may constitute the second inorganic encapsulation layer 143, as shown in FIG. 10(f).

Through the above operations, the encapsulation structure layer 14 may be obtained.

In some embodiments, a wiring layer may be formed on a side of the encapsulation structure layer 14 away from the driving structure layer 11. The wiring layer may be formed by a spraying method, etc.

As shown in FIG. 11, FIG. 11 is a schematic structural view of a display device according to some embodiments of the present disclosure.

In some embodiments, a display device 100 may be provided. The display device 100 may be configured in fields such as tablets, mobile phones, in-vehicle displays, and lighting.

The display device 100 may include a display panel 10. The structure and function of the display panel 10 may be the same as or similar to those of the display panel 10 in the above embodiments, and the same technical effects may be achieved. For details, reference may be made to the above detailed description, which will not be repeated here.

The display panel 10 in the display device 100 may adopt the display panel 10 in the above embodiments. The display panel 10 may have a display region 1 and a border region 2 located around the display region 1. The display panel 10 may include a driving structure layer 11 and an encapsulation structure layer 14 sequentially stacked on one another. The display panel 10 may further include a dam structure 21. The dam structure 21 may be arranged in the border region 2 and may be arranged between the driving structure layer 11 and the encapsulation structure layer 14. The dam structure 21 may include a thickened structure 211, a body structure 212, and an eave structure 213 sequentially stacked in a direction from the driving structure layer 11 to the encapsulation structure layer 14. At least a side end of the eave structure 213 may extend beyond a top surface of the body structure 212. An orthographic projection of a top surface of a part of the thickened structure 211 in contact with the body structure 212 onto a bottom surface of the eave structure 213 may not exceed or extend beyond an edge of the side end of the bottom surface of the eave structure 213 that extends beyond the body structure 212. The dam structure 21 provided in some embodiments of the present disclosure, by arranging in such a way that the orthographic projection of the top surface of the part of the thickened structure 211 in contact with the body structure 212 onto the bottom surface of the eave structure 213 may not extend beyond the edge of the side end of the bottom surface of the eave structure 213 that extends beyond the body structure 212, may reduce the probability of a void 22 being formed between a part of the encapsulation structure layer 14 covering the side end of the bottom surface of the eave structure 213 extending beyond the body structure 212 and another part of the encapsulation structure layer 14 covering the top surface of the thickened structure 211, thereby improving the reliability of the display panel 10.

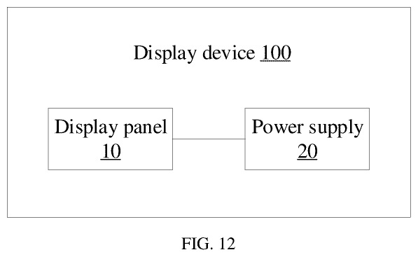

As shown in FIG. 12, FIG. 12 is a schematic structural view of a display device according to some embodiments of the present disclosure. The display device 100 may further include a power supply 20. The power supply 20 may be connected to the display panel 10 and configured to supply power to the display panel 10.

The above are merely embodiments of the present disclosure and are not intended to limit the scope of patent protection of the present disclosure. Any equivalent structural or procedural transformations made based on the content of the specification and drawings of the present disclosure, or any direct or indirect application in other related technical fields, shall likewise fall within the scope of protection of the present disclosure.

1. A display panel, having a display region and a border region located around the display region, the display panel comprising:
a driving structure layer;
an encapsulation structure layer, wherein the driving structure layer and the encapsulation structure layer are sequentially stacked on one another; and
one or more dam structures, arranged in the border region and arranged between the driving structure layer and the encapsulation structure layer, wherein each of the one or more dam structures comprises:
a thickened structure;
a body structure; and
an eave structure, wherein the thickened structure, the body structure, and the eave structure are sequentially stacked in a direction from the driving structure layer to the encapsulation structure layer, at least a side end of the eave structure extends beyond a top surface of the body structure, and an orthographic projection of a top surface of a part of the thickened structure in contact with the body structure onto a bottom surface of the eave structure is located within the bottom surface of the eave structure.

2. The display panel as claimed in claim 1, wherein the thickened structure comprises a planarization layer and a pixel defining layer, the pixel defining layer is located between the planarization layer and the body structure, and at least an end portion of the bottom surface of the eave structure away from the display region extends beyond an end portion of a top surface of the pixel defining layer in contact with the dam structure that corresponds to the eave structure.

3. The display panel as claimed in claim 2, wherein the encapsulation structure layer comprises a first inorganic encapsulation layer, an organic encapsulation layer, and a second inorganic encapsulation layer sequentially stacked in a direction away from the pixel defining layer, and a total thickness of the thickened structure and the body structure is greater than twice a thickness of the first inorganic encapsulation layer.

4. The display panel as claimed in claim 3, wherein a part of the eave structure extending beyond the top surface of the body structure, a sidewall surface of the body structure, and the top surface of a part of the thickened structure cooperatively define a recess on a sidewall surface of each of the one or more dam structures, the first inorganic encapsulation layer covers an inner wall surface of the recess, the second inorganic encapsulation layer fills and covers an opening of the recess, and a sidewall surface of the second inorganic encapsulation layer away from each of the one or more dam structures is flat.

5. The display panel as claimed in claim 3, wherein a minimum distance between an end surface of the first inorganic encapsulation layer on a side away from the display region and an edge of a bottom surface of the planarization layer in an outermost dam structure of the one or more dam structures on a side close to the end surface of the first inorganic encapsulation layer is not less than 2 micrometers.

6. The display panel as claimed in claim 2, wherein a conductive isolation structure is arranged on the pixel defining layer in the display region, the conductive isolation structure comprises a conductive structure arranged on the pixel defining layer and a roof structure arranged on the conductive structure, an orthographic projection of the conductive structure onto the driving substrate is at least partially overlapped with an orthographic projection of an anode electrode onto the driving substrate and an overlapped region is formed, a plurality of conductive vias are defined in a part of the pixel defining layer in the overlapping region, and the conductive structure is connected to the anode electrode through at least one of the plurality of the conductive vias.

7. The display panel as claimed in claim 6, wherein the body structure and the conductive structure are arranged spaced apart from each other in the same layer, and the eave structure and the roof structure are arranged spaced apart from each other in the same layer.

8. The display panel as claimed in claim 1, wherein the eave structure comprises a first side end and a second side end arranged opposite to each other, one of the first side end and the second side end is close to the display region, another one of the first side end and the second side end is away from the display region; the first side end extends beyond the top surface of the body structure, and an orthographic projection of the second side end onto the top surface of the body structure is aligned with an edge of the top surface of the body structure; or
the orthographic projection of the second side end onto the top surface of the body structure is located within the top surface of the body structure, enabling an end surface of the second side end, the top surface of a part of the body structure, and a sidewall surface of the body structure close to the second side end to form a stepped structure.

9. A method of manufacturing a display panel, comprising:
obtaining a pre-processed panel, the pre-processed panel having a display region and a border region located around the display region, the pre-processed panel comprising a driving structure layer and a thickened layer sequentially stacked on one another, a barrier structure being arranged on the thickened layer in the border region, the barrier structure comprising a body structure and an eave structure stacked in a direction away from the thickened layer, and at least one end of the eave structure extending beyond a top surface of the body structure;
sequentially removing a part of the thickened layer on a side of the eave structure extending beyond the top surface of the body structure to form a thickened structure on a side of the body structure away from the eave structure, and the thickened structure and the barrier structure cooperatively constituting a dam structure; wherein an orthographic projection of a top surface of a part of the thickened structure in contact with the body structure onto a bottom surface of the eave structure does not exceed an edge of a side end of the bottom surface of the eave structure extending beyond the body structure; and
forming an encapsulation structure layer on a side of the driving structure layer where the dam structure is arranged.

10. The method as claimed in claim 9, wherein the sequentially removing a part of the thickened layer on a side of the eave structure extending beyond a top surface of the body structure to form a thickened structure on a side of the body structure away from the eave structure, comprises:
forming a first photoresist layer on a side of the driving structure layer where the barrier structure is arranged;
forming a first window in the first photoresist layer, wherein a surface of the barrier structure and a surface of the thickened layer surrounding the barrier structure are exposed through the first window, and the thickened layer comprises a planarization layer and a pixel defining layer stacked in a direction away from the driving structure layer; and
removing at least the thickened layer within the first window that is located on an outer side of an orthographic projection of the eave structure onto the thickened structure by dry etching to form the thickened structure on the side of the body structure away from the eave structure.

11. The method as claimed in claim 10, wherein the pre-processed panel further comprises a plurality of metal layers that are spaced apart from each other, each of the plurality of metal layers is arranged between the thickened layer and a driving electrode, and a material of the thickened layer is different from a material of each of the plurality of metal layers; and
wherein the removing at least the thickened layer within the first window that is not covered by an orthographic projection of the eave structure by dry etching, comprises:
removing a part of the thickened layer within the first window that is located on the outer side of the orthographic projection of the eave structure onto the thickened layer by dry etching until the plurality of metal layers are exposed.

12. The method as claimed in claim 9, wherein the forming an encapsulation structure layer on a side of the driving structure layer where the dam structure is arranged, comprises:
depositing an inorganic material on a surface of the side of the driving structure layer where the dam structure is arranged to obtain a first inorganic encapsulation layer; wherein the first inorganic encapsulation layer covers all exposed surfaces of the driving structure layer on the side of the driving structure layer where the dam structure is arranged and an inner wall surface of a recess defined on a sidewall surface of the dam structure, and wherein the recess on the sidewall surface of the dam structure is defined by a part of the eave structure extending beyond the top surface of the body structure, a sidewall surface of the body structure, and the top surface of a part of the thickened structure;
forming an organic encapsulation layer on a part of the first inorganic encapsulation layer which is located on a side of the dam structure that is close to the display region;
depositing an inorganic material on the organic encapsulation layer and the dam structure to form a first sub-inorganic encapsulation layer;
thinning a surface of the first sub-inorganic encapsulation layer away from the driving structure layer to obtain a second sub-inorganic encapsulation layer; wherein a thickness of a part of the second sub-inorganic encapsulation layer covering the inner wall surface of the recess is greater than a thickness of another part of the second sub-inorganic encapsulation layer covering the top surface of the dam structure; and
depositing another inorganic material on an exposed surface of the second sub-inorganic encapsulation layer and thinning the another inorganic material until the inorganic material fully fills the recess, wherein at least the first sub-inorganic encapsulation layer and the second sub-inorganic encapsulation layer cooperatively serve as a second inorganic encapsulation layer.

13. A display device, comprising a display panel, having a display region and a border region located around the display region, the display panel comprising:
a driving structure layer;
an encapsulation structure layer, wherein the driving structure layer and the encapsulation structure layer are sequentially stacked on one another; and
one or more dam structures, arranged in the border region and arranged between the driving structure layer and the encapsulation structure layer, wherein each of the one or more dam structures comprises:
a thickened structure;
a body structure; and
an eave structure, wherein the thickened structure, the body structure, and the eave structure are sequentially stacked in a direction from the driving structure layer to the encapsulation structure layer, at least a side end of the eave structure extends beyond a top surface of the body structure, and an orthographic projection of a top surface of a part of the thickened structure in contact with the body structure onto a bottom surface of the eave structure is located within the bottom surface of the eave structure; and
a power supply, connected to the display panel and configured to supply power to the display panel.

14. The display device as claimed in claim 13, wherein the thickened structure comprises a planarization layer and a pixel defining layer, the pixel defining layer is located between the planarization layer and the body structure, and at least an end portion of the bottom surface of the eave structure away from the display region extends beyond an end portion of a top surface of the pixel defining layer in contact with the dam structure that corresponds to the eave structure.

15. The display device as claimed in claim 14, wherein the encapsulation structure layer comprises a first inorganic encapsulation layer, an organic encapsulation layer, and a second inorganic encapsulation layer sequentially stacked in a direction away from the pixel defining layer, and a total thickness of the thickened structure and the body structure is greater than twice a thickness of the first inorganic encapsulation layer.

16. The display device as claimed in claim 15, wherein a part of the eave structure extending beyond the top surface of the body structure, a sidewall surface of the body structure, and the top surface of a part of the thickened structure cooperatively define a recess on a sidewall surface of each of the one or more dam structures, the first inorganic encapsulation layer covers an inner wall surface of the recess, the second inorganic encapsulation layer fills and covers an opening of the recess, and a sidewall surface of the second inorganic encapsulation layer away from each of the one or more dam structures is flat.

17. The display device as claimed in claim 15, wherein a minimum distance between an end surface of the first inorganic encapsulation layer on a side away from the display region and an edge of a bottom surface of the planarization layer in an outermost dam structure of the one or more dam structures on a side close to the end surface of the first inorganic encapsulation layer is not less than 2 micrometers.

18. The display device as claimed in claim 14, wherein a conductive isolation structure is arranged on the pixel defining layer in the display region, the conductive isolation structure comprises a conductive structure arranged on the pixel defining layer and a roof structure arranged on the conductive structure, an orthographic projection of the conductive structure onto the driving substrate is at least partially overlapped with an orthographic projection of an anode electrode onto the driving substrate and an overlapped region is formed, a plurality of conductive vias are defined in a part of the pixel defining layer in the overlapping region, and the conductive structure is connected to the anode electrode through at least one of the plurality of the conductive vias.

19. The display device as claimed in claim 18, wherein the body structure and the conductive structure are arranged spaced apart from each other in the same layer, and the eave structure and the roof structure are arranged spaced apart from each other in the same layer.

20. The display device as claimed in claim 13, wherein the eave structure comprises a first side end and a second side end arranged opposite to each other, one of the first side end and the second side end is close to the display region, another one of the first side end and the second side end is away from the display region; the first side end extends beyond the top surface of the body structure, and an orthographic projection of the second side end onto the top surface of the body structure is aligned with an edge of the top surface of the body structure; or
the orthographic projection of the second side end onto the top surface of the body structure is located within the top surface of the body structure, enabling an end surface of the second side end, the top surface of a part of the body structure, and a sidewall surface of the body structure close to the second side end to form a stepped structure.
